(19) United States
(12) Patent Application Publication
(10) Pub. No.: US 2012/0009710 A1
(43) Pub. Date: Jan. 12, 2012

(54) METHOD OF FORMING LDD OF TFT, METHOD OF FABRICATING TFT AND ORGANIC LIGHT EMITTING DEVICE USING THE METHOD

(76) Inventor: Young-Il Kim, Yongin-city (KR)

(21) Appl. No.: 13/038,781

(22) Filed: Mar. 2, 2011

(30) Foreign Application Priority Data
Jul. 7, 2010 (KR) 1020100065464

(51) Int. Cl. H01L 21/336; H01L 51/56

(52) U.S. Cl. 438/46; 438/158; 257/E21.414; 257/E51.018

(57) ABSTRACT

A method of forming a lightly doped drain (LDD) of a thin film transistor (TFT) is disclosed. The method includes the following steps. A gate electrode is formed on a front side of a substrate. A gate insulating layer is formed on the gate electrode and the front side of the substrate. An activation layer is formed on the gate insulating layer. Low-concentration ion implantation is performed on the activation layer via a back side of the substrate. High-concentration ion implantation is performed on the activation layer that has been subjected to the low-concentration ion implantation, via the front side of the substrate, thereby forming a low-concentration impurity region and a high-concentration impurity region in the activation layer. The method may further include forming a high-concentration ion implantation mask on the activation layer.

### CROSS-REFERENCE TO RELATED APPLICATIONS

This application claims the benefit of Korean Patent Application No. 10-2010-0065464, filed on Jul. 7, 2010, in the Korean Intellectual Property Office, the entire content of which is incorporated herein by reference.

### BACKGROUND

1. Field

Aspects of embodiments according to the present invention relate to a thin film transistor (TFT), and more particularly, to a method of forming a lightly doped drain (LDD) of a TFT and a method of fabricating a TFT using the method.

2. Description of the Related Art

A thin film transistor (TFT) is a particular kind of field effect transistor. TFTs are fabricated by forming a semiconductor thin film on an insulating support substrate. Like other field effect transistors, a TFT includes a gate, a drain, and a source. The TFT performs a switching operation by controlling a voltage applied to the gate to either allow a current to flow between the source and the drain or to prevent a current from flowing therebetween. In general, TFTs are used in, for example, sensors, memory devices, and optical devices, and are also used, for example, in pixel switching circuits or in operating circuits of a flat panel display.

Increasing demand for large and high-quality displays has led to development of high-performance devices. Thus, a polycrystalline silicon TFT (poly-Si TFT), which has an electron mobility rate of a few to several hundreds cm²/Vs, is often used instead of an amorphous-silicon TFT (a-Si TFT), which has an electron mobility rate of 0.5 to 1 cm²/Vs. A poly-Si TFT allows a data operating circuit or peripheral circuit requiring a high electron mobility rate to be mounted on a substrate, and a channel thereof may be formed small to increase an aperture ratio of a screen. In addition, since there is no limitation on an interconnection pitch for connection to an operating circuit, and since there is an increasing pixel count due to the installation of the small operating circuit, high-resolution may be obtained. In addition, the operating voltage and electric power consumption may be reduced, and device characteristics may be far less degraded.

As a method of fabricating a poly-Si TFT, there is a low-temperature polycrystalline silicon (LTPS) technique for crystallizing amorphous silicon deposited at low temperature into polycrystalline silicon. The crystallizing may be performed, for example, by an excimer laser crystallization (ELC) technique or a crystallization technique using a metal as a catalyst.

A LTPS TFT may be a top gate-type TFT or a bottom gate-type TFT. The top gate-type TFT is stable in terms of characteristics and is easily manufactured. In addition, since a gate electrode is not formed under a silicon layer, an amorphous silicon layer is easily crystallized.

Concerning a bottom gate-type LTPS TFT, a TFT manufacturing line may be designed by modifying a manufacturing line for an amorphous silicon TFT, since the bottom gate-type LTPS TFT and the amorphous silicon TFT may have the same structure. In addition, since a silicon layer is formed on a gate insulating layer, impurities contained in a glass substrate may not permeate into the silicon layer and irradiation of external light to a gate electrode may be blocked, resulting in no need for a separate blocking layer.

Meanwhile, an important characteristic of a TFT is a low l_{off} current characteristic. However, usually, poly-Si TFTs have a high leakage current. Thus, reducing the leakage current of poly-Si TFTs is an issue to be addressed. Leakage current may be increased due to an electric field between a gate and a drain, and the leakage current may be reduced by using an offset structure, or a double gate or lightly doped drain (LDD) structure.

Concerning a top gate-type LTPS TFT, an LDD region symmetric with respect to a gate electrode is formed by self-aligning using a gate electrode. In a bottom gate-type LTPS TFT, however, an activation layer is formed on the gate electrode and thus it is difficult to form an LDD region symmetric with respect to the gate electrode. Asymmetric LDD regions may lead to an increase of a pinch-off characteristic and may cause leakage current.

### SUMMARY

One or more embodiments of the present invention include a method of forming a symmetric lightly doped drain (LDD) of a bottom gate-type thin film transistor (TFT). One or more embodiments of the present invention include a method of fabricating a bottom gate-type TFT having a reduced leakage current due to inclusion of a symmetric LDD structure, and a method of fabricating an organic light emitting device including the bottom gate-type TFT. Additional aspects will be set forth in part in the description that follows and, in part, will be apparent from the description, or may be learned by practice of the presented embodiments.

According to an exemplary embodiment of the present invention, a method of forming a lightly doped drain (LDD) of a thin film transistor (TFT) is provided. The method includes: forming a gate electrode on a front side of a substrate; forming a gate insulating layer on the gate electrode and the front side of the substrate; forming an activation layer on the gate insulating layer; performing low-concentration ion implantation on the activation layer via a back side of the substrate; and performing high-concentration ion implantation on the activation layer that has been subjected to the low-concentration ion implantation, via the front side of the substrate, thereby forming a low-concentration impurity region and a high-concentration impurity region in the activation layer.

The low-concentration ion implantation may be performed using the gate electrode as a mask.

The low-concentration ion implantation may be performed at inclination angles with respect to the substrate.

The gate electrode may include side surfaces inclined at inclination angles smaller than 90 degrees with respect to the substrate.

The inclination angles may be controlled to be such that the low-concentration ion implantation is performed on a portion of the activation layer overlapping the gate electrode.

The high-concentration ion implantation may be performed in a direction perpendicular to the substrate.

The method may further include forming a high-concentration ion implantation mask after the low-concentration ion implantation but before the high-concentration ion implantation.

The method may further include forming a high-concentration ion implantation mask after forming the activation layer but before the low-concentration ion implantation.

The method may further include forming a high-concentration ion implantation mask after forming the activation layer, wherein a width of the high-concentration ion implantation mask is greater than a width of the gate electrode.

The low-concentration ion implantation and the high-concentration ion implantation may be performed using an n-type semiconducting material.

The low-concentration ion implantation and the high-concentration ion implantation may be performed using phosphorous (P) or arsenic (As).

The low-concentration ion implantation and the high-concentration ion implantation are performed using a p-type semiconducting material.

The low-concentration ion implantation and the high-concentration ion implantation may be performed using boron (B).

The activation layer may include polycrystalline silicon.

The forming of the activation layer may include: forming an amorphous silicon layer on the gate insulating layer; and crystallizing the amorphous silicon layer.

The crystallizing of the amorphous silicon layer may be performed by excimer laser annealing (ELA).

The crystallizing of the amorphous silicon layer may be performed by heat treatment using a metallic catalyst.

The method may further include forming a buffer layer on the substrate before the forming of the gate electrode.

According to another exemplary embodiment of the present invention, a method of forming a thin film transistor (TFT) is provided. The method includes: forming a gate electrode on a front side of a substrate; forming a gate insulating layer on the gate electrode and the front side of the substrate; forming an activation layer on the gate insulating layer; performing low-concentration ion implantation on the activation layer via a back side of the substrate; performing high-concentration ion implantation on the activation layer that has been subjected to the low-concentration ion implantation, via the front side of the substrate, thereby forming a low-concentration impurity region and a high-concentration impurity region in the activation layer; forming a first interlayer insulating layer on the activation layer that has been subjected to the high-concentration ion implantation and the gate insulating layer; and forming a source/drain electrode that passes through the first interlayer insulating layer and contacts the high-concentration impurity region.

According to yet another exemplary embodiment of the present invention, a method of forming an organic electroluminescent device is provided. The method includes: forming a gate electrode on a front side of a substrate; forming a gate insulating layer on the gate electrode and the front side of the substrate; forming an activation layer on the gate insulating layer; performing low-concentration ion implantation on the activation layer via a back side of the substrate; performing high-concentration ion implantation on the activation layer that has been subjected to the low-concentration ion implantation, via the front side of the substrate, thereby forming a low-concentration impurity region and a high-concentration impurity region in the activation layer; forming a first interlayer insulating layer on the activation layer that has been subjected to the high-concentration ion implantation and the gate insulating layer; forming a source/drain electrode that passes through the first interlayer insulating layer and contacts the high-concentration impurity region; forming a second interlayer insulating layer on the first interlayer insulating layer and the source/drain electrode; forming a first pixel electrode that passes through the second interlayer insulating layer and contacts the source/drain electrode, and extends onto the second interlayer insulating layer; forming a pixel defining layer on the second interlayer insulating layer and the first pixel electrode; forming an organic layer comprising an emission layer on a portion of the first pixel electrode defined by the pixel defining layer; and forming a second pixel electrode on the organic layer.

### BRIEF DESCRIPTION OF THE DRAWINGS

These and/or other aspects will become apparent and more readily appreciated from the following description of the embodiments, taken in conjunction with the accompanying drawings of which:

FIG. 1 is a flowchart for illustrating a method of forming a lightly doped drain (LDD) of a thin film transistor (TFT) according to an embodiment of the present invention;

FIG. 2 is a flowchart for illustrating a method of forming a LDD of a TFT according to another embodiment of the present invention; and

FIGS. 3A through 3H are sectional views for illustrating a method of forming a LDD of a TFT according to an embodiment of the present invention.

### DETAILED DESCRIPTION

Reference will now be made in detail to embodiments, examples of which are illustrated in the accompanying drawings, wherein thicknesses of a layer and a region may be exaggerated for clarity and like reference numerals refer to like elements throughout. In this regard, the present embodiments may have different forms and should not be construed as being limited to the descriptions set forth herein. Accordingly, the embodiments are merely described below, by referring to the figures, to explain aspects of the present invention.

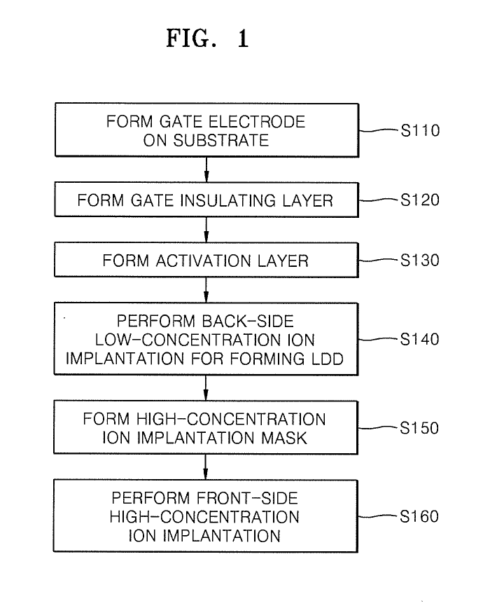

FIG. 1 is a flowchart for illustrating a method of forming a lightly doped drain (LDD) of a thin film transistor (TFT) according to an embodiment of the present invention.

Referring to FIG. 1, a gate electrode is formed on a substrate (S110). The substrate may be formed, for example, of transparent glass or a transparent plastic material. The gate electrode may be formed of a metal such as titanium (Ti), platinum (Pt), rubidium (Ru), copper (Cu), gold (Au), silver (Ag), molybdenum (Mo), chromium (Cr), aluminum (Al), tantalum (Ta), tungsten (W), or an alloy thereof; or a conductive oxide such as tin oxide, zinc oxide, indium oxide, indium tin oxide (ITO), indium zinc oxide (IZO), gallium zinc oxide (GZO), indium gallium oxide (IGO), or aluminum zinc oxide (AZO).

A gate insulating layer is formed on the gate electrode and the substrate (S120). The gate insulating layer may be, for example, a silicon oxide layer, a silicon nitride layer, or a stack thereof.

An activation layer is formed on the gate insulating layer (S130). For example, the activation layer may be a polycrystalline silicon layer. The polycrystalline silicon layer may be formed by, for example, crystallizing an amorphous silicon layer using a laser or a metallic catalyst.

Low-concentration ion implantation is performed on a back side of the substrate to form the LDD in the activation layer (S140). The low-concentration ion implantation may be performed at inclination angles with respect to the substrate (that is, in a direction not perpendicular to the substrate) to control the size of a low-concentration impurity region for the LDD. In this regard, since the low-concentration ion implantation occurs through the substrate, the gate electrode functions as an ion implantation mask. Since the low-concentration ion implantation is performed at inclination angles with respect to the substrate, ion implantation may also occur in a portion of the activation layer that corresponds to the gate electrode. Thus, the low-concentration ion implantation may occur in both a portion of the activation layer that is not masked by the gate electrode and a portion of the activation layer that is masked by the gate electrode, where “masked” in this case is in reference to ion implantation being performed at no inclination angle (i.e., perpendicular) with respect to the substrate.

A high-concentration ion implantation mask is formed on the activation layer that has been subjected to the low-concentration ion implantation (S150). The high-concentration ion implantation mask covers the region where the ion implantation is not performed and the low-concentration impurity region for the LDD in the activation layer. The high-concentration ion implantation mask may be formed of, for example, photoresist.

High-concentration ion implantation is performed on a front side of the substrate using the high-concentration ion implantation mask (S160). The high-concentration ion implantation may be performed in a direction perpendicular to the substrate.

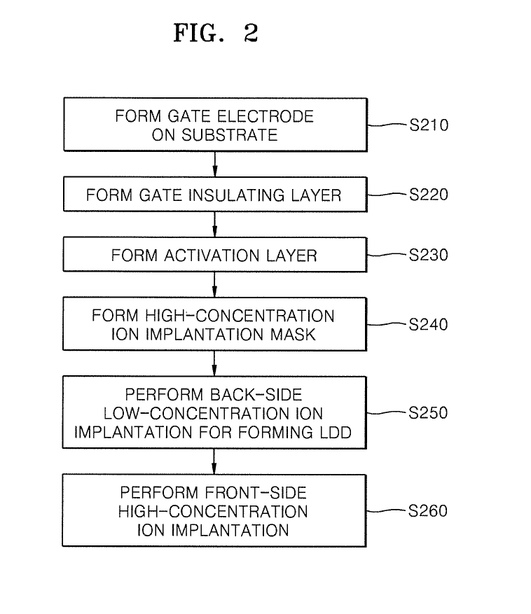

FIG. 2 is a flowchart for illustrating a method of forming an LDD of a TFT according to another embodiment of the present invention. The embodiment illustrated in FIG. 2 is different from the previous embodiment illustrated in FIG. 1 in that the forming of the high-concentration ion implantation mask on the front side of the substrate is performed before the low-concentration ion implantation for forming the LDD. That is, the gate electrode is formed on the substrate (S210), the gate insulating layer is formed on the gate electrode (S220), the activation layer is formed on the gate electrode and the substrate (S230), and then the high-concentration ion implantation mask is formed on the activation layer (S240). Then, the low-concentration ion implantation for forming the LDD is performed on the back side of the substrate using the gate electrode as a mask (S240). The low-concentration ion implantation for forming the LDD may be performed at inclination angles with respect to the substrate. The high-concentration ion implantation is performed on the front side of the substrate using the high-concentration ion implantation mask (S160). The other operations except for the forming of the high-concentration ion implantation mask are the same as in the previous embodiment illustrated in FIG. 1 and their detailed descriptions will not be repeated.

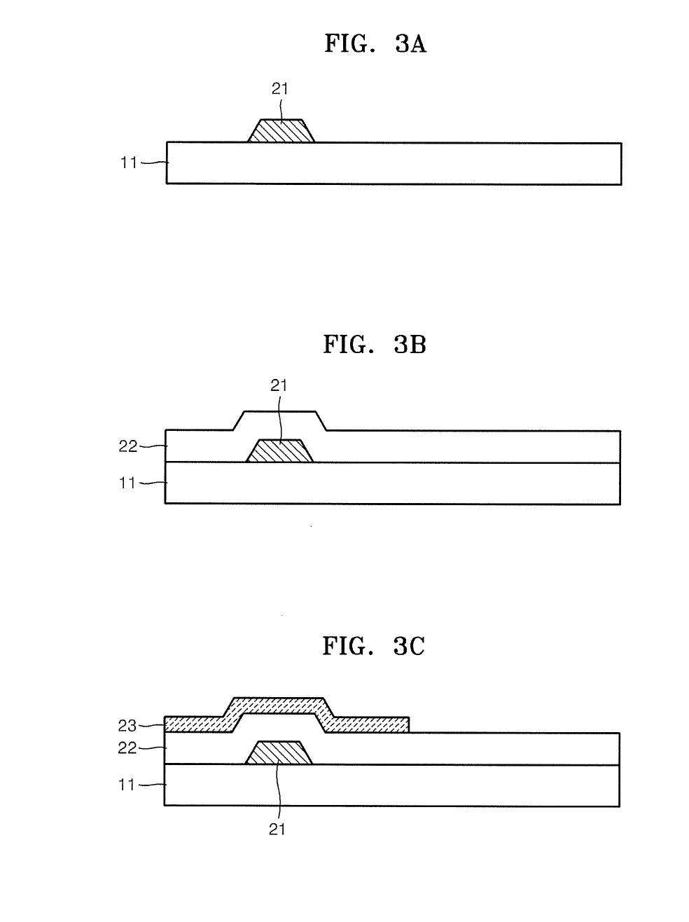

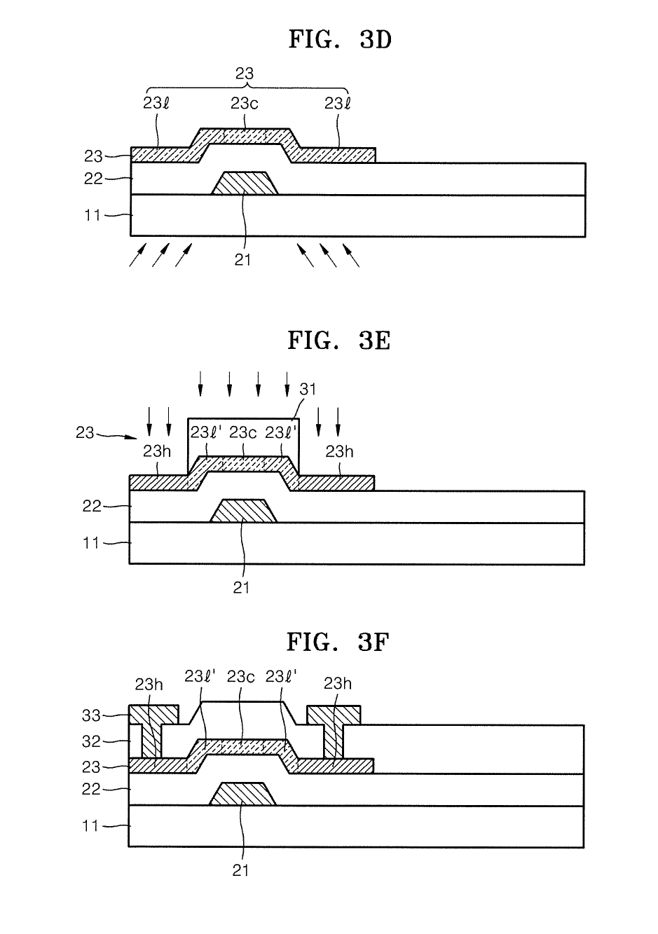

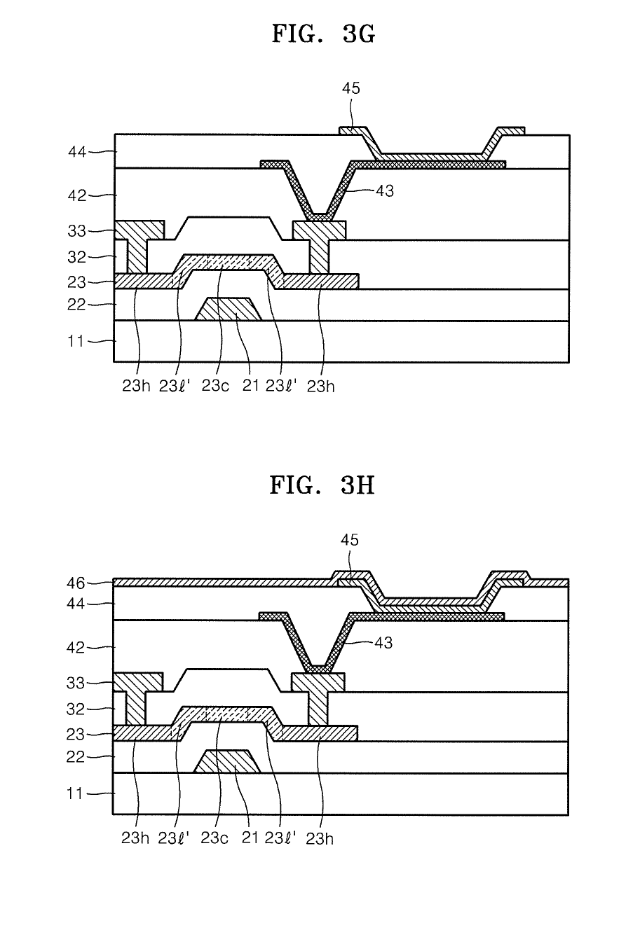

FIGS. 3A through 3H are sectional views for sequentially explaining a method of forming an LDD of a TFT according to an embodiment of the present invention.

Referring to FIG. 3A, a gate electrode 21 is formed on a substrate 11. The substrate 11 may be formed of transparent glass or a transparent plastic material, and may also be formed of other materials. The gate electrode 21 may be formed of a metal such as Ti, Pt, Ru, Cu, Au, Ag, Mo, Cr, Al, Ta, W, or an alloy thereof; or a conductive oxide such as tin oxide, zinc oxide, indium oxide, ITO, IZO, GZO, IGO, or AZO. For example, the gate electrode 21 may be one selected from the group consisting of a Cu or Mo monometallic layer, a multi-metallic layer including a Mo layer, a Ti-containing metallic layer, and a Cr-containing metallic layer.

The gate electrode 21 may have side surfaces, each of which is inclined at inclination angles smaller than 90 degrees with respect to the substrate 11. However, selectively, the side surfaces of the gate electrode 21 may also be perpendicular to the substrate 11. Depending on the particular layout, the inclination angles of the side surfaces of the gate electrode 21 may not be a critical factor in determining an ion implantation region when the low-concentration ion implantation for forming the LDD is performed. In other embodiments, before the gate electrode 21 is formed, a buffer layer (not shown) may be formed on the substrate 11 and the gate electrode 21 may be formed on the buffer layer.

Referring to FIG. 3B, a gate insulating layer 22 is formed on the gate electrode 21 and the substrate 11. The gate insulating layer 22 may be a silicon oxide layer, a silicon nitride layer, or a stack thereof. The gate insulating layer 22 may be formed by low-pressure chemical vapor deposition (LPCVD) or plasma enhanced chemical vapor deposition (PECVD.)

Referring to FIG. 3C, an activation layer 23 is formed on the gate insulating layer 22. The activation layer 23 may be a polycrystalline silicon layer. The polycrystalline silicon layer may be formed by crystallizing an amorphous silicon layer using a laser or a metallic catalyst.

The amorphous silicon layer may be formed by LPCVD or PECVD at a temperature of 400° C. or less. The crystallizing of the amorphous silicon layer may be performed by excimer laser annealing (ELA.) Concerning the excimer laser annealing (ELA), a pulse laser beam of an ultraviolet region that is easily absorbed by the amorphous silicon layer is irradiated to the amorphous silicon layer, thereby melting the amorphous silicon layer to form the polycrystalline silicon layer. The crystallization of the amorphous silicon layer may also be performed using a metallic catalyst. In this case, the amorphous silicon layer may be crystallized by heat treatment using a metallic catalyst as a seed. Then, the polycrystalline silicon layer is patterned to form the activation layer 23.

Referring to FIG. 3D, low-concentration ion implantation for forming an LDD region is performed on a back side of the substrate 11. As indicated by arrows in FIG. 3D, the low-concentration ion implantation is performed on the back side of the substrate 11 at inclination angles with respect to the substrate 11. By performing the low-concentration ion implantation, a low-concentration impurity region 23l symmetric about the gate electrode 21 is formed. The activation layer 23 includes a channel region 23c.

Since the low-concentration ion implantation is performed through the substrate 11, the gate electrode 21 may function as an ion implantation mask. Since the gate electrode 21 functions as an ion implantation mask, the low-concentration impurity region 23l may be formed symmetric about the gate electrode 21. When the low-concentration impurity region 23l is symmetric about the gate electrode 21, an off-line current l_{off} characteristic may be improved.

In addition, since the low-concentration ion implantation is performed at inclination angles with respect to the substrate 11, the ion implantation may also occur in a portion of the activation layer 23 overlapping the gate electrode 21. As a result, the low-concentration impurity region 23l is formed in a portion of the activation layer 23 that is not masked by the gate electrode 21 and a portion of the portion of the activation layer 23 overlapping the gate electrode 21. The size of the low-concentration impurity region 23l may be controlled by controlling the inclination angles of the ion implantation. That is, for example, if the inclination angles of the ion implantation with respect to the substrate 11 are decreased (from 90 degrees, or perpendicular to the substrate 11), the low-concentration impurity region 23l on the gate electrode 21 is increased and thus the size of the low-concentration impurity region 23l is increased.

When the TFT is a PMOS TFT, a p-type dopant for forming the LDD region, for example, boron (B), may be added to the activation layer 23. An ion implantation source for B may be, for example, B₂H₆. When the TFT is an NMOS TFT, an n-type dopant for forming the LDD region, for example, phosphorous (P) or arsenic (As), may be added to the activation layer 23. An ion implantation source for P may be, for example, PH₃.

Referring to FIG. 3E, a high-concentration ion implantation mask 31 is formed on the activation layer 23 that has been subjected to the low-concentration ion implantation and high-concentration ion implantation is performed on a front side of the substrate 11. The high-concentration ion implantation mask 31 is formed covering a portion of the activation layer 23 that is to be a low-concentration LDD region 23l′. To do this, the width of the high-concentration ion implantation mask 31 may be greater than the width of the gate electrode 21. The high-concentration ion implantation mask 31 may be formed of, for example, photoresist. The high-concentration ion implantation may be performed in a direction perpendicular to the substrate 11. A high-concentration impurity region 23h is formed in a portion of the activation layer 23 exposed by the high-concentration ion implantation mask 31.

Since the high-concentration ion implantation may not be performed by self-aligning, the formed high-concentration impurity region 23h may not be symmetric about the gate electrode 21. However, since the off-line current l_{off} characteristic is largely dependent on symmetry of the low-concentration LDD region 23l′, the non-symmetry of the high-concentration impurity region 23h does not substantially affect the off-line current l_{off} characteristic.

Like the low-concentration ion implantation, when the TFT is a PMOS TFT, the high-concentration ion implantation may be performed using B as a dopant. Similarly, when the TFT is an NMOS TFT, the high-concentration ion implantation may be performed using P or As as a dopant.

Referring to FIG. 3F, the high-concentration ion implantation mask 31 is removed and a first interlayer insulating layer 32 is formed. The first interlayer insulating layer 32 may be formed of silicon oxide. Then, contact holes are formed in the first interlayer insulating layer 32 to expose the high-concentration impurity region 23h of the activation layer 23, and the contact hole is filled with a conducting material to form a source/drain electrode 33. The conducting material for forming the source/drain electrode may be, for example, Au, Ag, Cu, Ni, Pt, Pd, Al, Mo, W, Ti, or an alloy thereof.

Referring to FIG. 3G, a second interlayer insulating layer 42 is formed on the source/drain electrode 33 and the first interlayer insulating layer 32. The second interlayer insulating layer 42 may be an organic layer or an inorganic layer. A first pixel electrode 43 may be formed passing through the second interlayer insulating layer 42 to contact the source/drain electrode 33 and extending onto the second interlayer insulating layer 42. The first pixel electrode 43 may be formed of a transparent and conductive oxide material such as ITO or IZO.

Referring to FIG. 3H, a pixel defining layer 44 is formed on the first pixel electrode 43 and the second interlayer insulating layer 42. The pixel defining layer 44 may be an organic layer or an inorganic layer. An opening exposing a portion of the first pixel electrode 43 is formed in the pixel defining layer 44 and an organic layer 45 is formed on the exposed portion of the first pixel electrode 43. The organic layer 45 includes an emission layer and may further include at least one layer selected from the group consisting of a hole injection layer, a hole transport layer, an electron transport layer, and an electron injection layer. A second pixel electrode 46 is formed on the organic layer 45. The second pixel electrode 46 may be formed of, for example, Mg, Ag, Al, Ca, or an alloy thereof.

In the embodiment illustrated in FIGS. 3A-3H, the low-concentration impurity region 23l is formed by the back-side ion implantation and then the high-concentration ion implantation mask 31 is formed. However, as described above, the high-concentration ion implantation mask 31 may instead be formed in advance and then the low-concentration impurity region 23l is formed by the back-side ion implantation and the high-concentration impurity region 23h is formed by the front-side ion implantation.

As described above, according to the one or more of the above embodiments of the present invention, in regard to a bottom gate-type TFT, by forming a low-concentration impurity region for a LDD by self-aligning by performing ion implantation on a back side of a substrate using a gate electrode as a mask, a formed LDD has symmetry and a TFT leakage current may be reduced.

It should be understood that the exemplary embodiments described herein should be considered in a descriptive sense only and not for purposes of limitation. Descriptions of features or aspects within each embodiment should typically be considered as available for other similar features or aspects in other embodiments. While the present invention has been particularly shown and described with reference to these exemplary embodiments, it will be understood by those of ordinary skill in the art that various changes in form and details may be made therein without departing from the spirit and scope of the present invention as defined by the following claims, and equivalents thereof.

What is claimed is:

1. A method of forming a lightly doped drain (LDD) of a thin film transistor (TFT), the method comprising:
forming a gate electrode on a front side of a substrate;
forming a gate insulating layer on the gate electrode and the front side of the substrate;
forming an activation layer on the gate insulating layer;
performing low-concentration ion implantation on the activation layer via a back side of the substrate; and
performing high-concentration ion implantation on the activation layer that has been subjected to the low-concentration ion implantation, via the front side of the substrate, thereby forming a low-concentration impurity region and a high-concentration impurity region in the activation layer.

2. The method of claim 1, wherein the low-concentration ion implantation is performed using the gate electrode as a mask.

3. The method of claim 1, wherein the low-concentration ion implantation is performed at inclination angles with respect to the substrate.

4. The method of claim 3, wherein the gate electrode comprises side surfaces inclined at inclination angles smaller than 90 degrees with respect to the substrate.

5. The method of claim 3, wherein the inclination angles are controlled to be such that the low-concentration ion implantation is performed on a portion of the activation layer overlapping the gate electrode.

6. The method of claim 1, wherein the high-concentration ion implantation is performed in a direction perpendicular to the substrate.

7. The method of claim 1, further comprising forming a high-concentration ion implantation mask after the low-concentration ion implantation but before the high-concentration ion implantation.

8. The method of claim 1, further comprising forming a high-concentration ion implantation mask after forming the activation layer but before the low-concentration ion implantation.

9. The method of claim 1, further comprising forming a high-concentration ion implantation mask after forming the activation layer, wherein a width of the high-concentration ion implantation mask is greater than a width of the gate electrode.

10. The method of claim 1, wherein the low-concentration ion implantation and the high-concentration ion implantation are performed using an n-type semiconducting material.

11. The method of claim 10, wherein the low-concentration ion implantation and the high-concentration ion implantation are performed using phosphorous (P) or arsenic (As).

12. The method of claim 1, wherein low-concentration ion implantation and the high-concentration ion implantation are performed using a p-type semiconducting material.

13. The method of claim 12, wherein the low-concentration ion implantation and the high-concentration ion implantation are performed using boron (B).

14. The method of claim 1, wherein the activation layer comprises polycrystalline silicon.

15. The method of claim 14, wherein the forming of the activation layer comprises:
forming an amorphous silicon layer on the gate insulating layer; and
crystallizing the amorphous silicon layer.

16. The method of claim 15, wherein the crystallizing of the amorphous silicon layer is performed by excimer laser annealing (ELA).

17. The method of claim 15, wherein the crystallizing of the amorphous silicon layer is performed by heat treatment using a metallic catalyst.

18. The method of claim 1, further comprising forming a buffer layer on the substrate before the forming of the gate electrode.

19. A method of forming a thin film transistor (TFT), the method comprising:
forming a gate electrode on a front side of a substrate;
forming a gate insulating layer on the gate electrode and the front side of the substrate;
forming an activation layer on the gate insulating layer;
performing low-concentration ion implantation on the activation layer via a back side of the substrate;
performing high-concentration ion implantation on the activation layer that has been subjected to the low-concentration ion implantation, via the front side of the substrate, thereby forming a low-concentration impurity region and a high-concentration impurity region in the activation layer;
forming a first interlayer insulating layer on the activation layer that has been subjected to the high-concentration ion implantation and the gate insulating layer; and
forming a source/drain electrode that passes through the first interlayer insulating layer and contacts the high-concentration impurity region.

20. A method of forming an organic electroluminescent device, the method comprising:
forming a gate electrode on a front side of a substrate;
forming a gate insulating layer on the gate electrode and the front side of the substrate;
forming an activation layer on the gate insulating layer;
performing low-concentration ion implantation on the activation layer via a back side of the substrate;
performing high-concentration ion implantation on the activation layer that has been subjected to the low-concentration ion implantation, via the front side of the substrate, thereby forming a low-concentration impurity region and a high-concentration impurity region in the activation layer;
forming a first interlayer insulating layer on the activation layer that has been subjected to the high-concentration ion implantation and the gate insulating layer;
forming a source/drain electrode that passes through the first interlayer insulating layer and contacts the high-concentration impurity region;
forming a second interlayer insulating layer on the first interlayer insulating layer and the source/drain electrode;
forming a first pixel electrode that passes through the second interlayer insulating layer and contacts the source/drain electrode, and extends onto the second interlayer insulating layer;
forming a pixel defining layer on the second interlayer insulating layer and the first pixel electrode;
forming an organic layer comprising an emission layer on a portion of the first pixel electrode defined by the pixel defining layer; and
forming a second pixel electrode on the organic layer.
